(19) United States
(12) Patent Application Publication
(10) Pub. No.: US 2026/0018540 A1
(43) Pub. Date: Jan. 15, 2026

(54) CIRCUIT DEVICE AND DISPLAY DEVICE INCLUDING THE SAME

(71) Applicant: LG ELECTRONICS INC., Seoul (KR)

(72) Inventors: Myungwhun CHANG, Seoul (KR); Yanghyun KIM, Seoul (KR); Inho SHIN, Seoul (KR); Sangwon WOO, Seoul (KR); Wonsik KIM, Seoul (KR); Donghyun KIM, Seoul (KR); Hongsung SONG, Seoul (KR)

(73) Assignee: LG ELECTRONICS INC., Seoul (KR)

(21) Appl. No.: 18/827,003

(22) Filed: Sep. 6, 2024

(30) Foreign Application Priority Data
Jul. 10, 2024 (WO) PCT/KR2024/009877

(51) Int. Cl. H01L 23/00; H01L 23/29

(52) U.S. Cl. CPC H01L 23/564; H01L 23/293

(57) ABSTRACT

Disclosed are a circuit device and a display device including the same. The circuit device may include a board, an electronic component mounted on the board, an IC chip meeting an upper surface of the electronic component, and a coating layer partially surrounding a side surface of the electronic component and having an upper surface spaced apart from the IC chip.

Pursuant to 35 U.S.C. § 119(a), the present application claims the benefit of earlier filing date and right of priority to the International Application No. PCT/KR2024/009877, filed on Jul. 10, 2024, the contents of which are hereby incorporated by reference herein in their entirety.

### BACKGROUND OF THE DISCLOSURE

### Field of the Disclosure

The present embodiments relate to a circuit device and a display device including the same, and more particularly, to a circuit device preventing moisture penetration into an electrode or an electronic component and a display device including the same.

### Discussion of the Related Art

In the field of integrated circuit technology, solder is formed on a substrate such as a Printed Circuit Board (PCB) and used as an external connection terminal.

In particular, solder paste is used to form solder, which is a material used when soldering electronic components to a Printed Circuit Board (PCB). Solder paste is made of alloy particles including lead and tin and a chemical substance called flux, and there is a problem that the flux remaining after the process should be additionally removed.

In addition, in the case of a high-temperature and humid environment, there is a problem that shorting between electrodes frequently occurs due to moisture penetration.

### SUMMARY OF THE DISCLOSURE

One object of the present disclosure is to provide a circuit device for preventing moisture penetration into an electrode or an electronic component by forming a coating layer made of an epoxy component and a display device including the same.

Another object of the present disclosure is to provide a circuit device and display device including the same, by which a flux is removed after a process by using a solder paste that does not contain a flux.

Additional advantages, objects, and features of the disclosure will be set forth in the disclosure herein as well as the accompanying drawings. Such aspects may also be appreciated by those skilled in the art based on the disclosure herein.

To achieve these objects and other advantages and in accordance with the purpose of the disclosure, as embodied and broadly described herein, a circuit device according to the present disclosure may include a board, an electronic component mounted on the board, an IC chip meeting an upper surface of the electronic component, and a coating layer partially surrounding a side surface of the electronic component and having an upper surface spaced apart from the IC chip.

The coating layer may surround an upper surface of the substrate.

The board may include a support layer and a protective layer located on the support layer, and a portion of the coating layer may surround the side surface of the electronic component while overlapping the protective layer.

A height of the coating layer may decrease in proportion to a distance from the electronic component.

A distance from the upper surface of the coating layer to the IC chip may be formed smaller than a half of a height of the electronic component.

The coating layer may be formed by a mixture containing an epoxy component.

A content of the epoxy component contained in the mixture may amount to 8 to 12 wt %.

In another aspect of the present disclosure, as embodied and broadly described herein, a display device according to the present disclosure may include a display panel, a board providing a driving signal to the display panel, an electronic component mounted on the board, an IC chip meeting an upper surface of the electronic component, and a coating layer partially surrounding a side surface of the electronic component and having an upper surface spaced apart from the IC chip.

The coating layer may surround an upper surface of the substrate.

The board may include a support layer and a protective layer located on the support layer, and a portion of the coating layer may surround the side surface of the electronic component while overlapping the protective layer.

A height of the coating layer may decrease in proportion to a distance from the electronic component.

A distance from the upper surface of the coating layer to the IC chip may be formed smaller than a half of a height of the electronic component.

The coating layer may be formed by a mixture containing an epoxy component.

Accordingly, the present disclosure provides the following effects and/or advantages.

According to embodiments, a short circuit may be prevented even in a high-temperature and high-humidity environment by providing a circuit device for preventing moisture penetration into an electrode or an electronic component by forming a coating layer made of an epoxy component and a display device including the same.

According to embodiments, a circuit device and display device including the same, in which a flux fails to remain even after a process using a solder paste that does not contain the flux, thereby providing a coating layer that serves as a waterproof film at the same time as a conventional flux.

The effects obtained by the present disclosure are not limited to the above-mentioned effects, and other effects not mentioned will be clearly understood by those skilled in the art to which the present disclosure pertains from the following description

### BRIEF DESCRIPTION OF THE DRAWINGS

The accompanying drawings, which are included to provide a further understanding of the disclosure and are incorporated in and constitute a part of the present application, illustrate embodiment(s) of the disclosure and together with the description serve to explain the principle of the disclosure. The above and other aspects, features, and advantages of the present disclosure will become more apparent upon consideration of the following description of preferred embodiments, taken in conjunction with the accompanying drawing figures. In the drawings:

FIG. 1 is a block diagram illustrating each configuration of a display device according to embodiments;

FIG. 2 is a perspective diagram illustrating an example of a display device according to embodiments;

FIG. 3 is an exploded perspective diagram illustrating an example of a display device according to embodiments;

FIG. 4 is a diagram illustrating a circuit device according to embodiments;

FIG. 5 is an enlarged diagram illustrating an electronic component of a circuit device according to embodiments; and

FIG. 6 and FIG. 7 are diagrams illustrating examples of a circuit device according to embodiments.

### DETAILED DESCRIPTION OF THE DISCLOSURE

Description will now be given in detail according to exemplary embodiments disclosed herein, with reference to the accompanying drawings. The same or equivalent components may be provided with the same reference numbers, and description thereof will not be repeated. As used herein, the suffixes “module” and “part” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification. As such, the present disclosure should be construed to extend to any alterations, equivalents and substitutes in addition to those which are particularly set out in the accompanying drawings.

Although the terms first, second, etc. may be used herein to describe various elements, these elements should not be limited by these terms. These terms are generally only used to distinguish one element from another.

It will be understood that when an element is referred to as being “connected with” another element, the element can be directly connected with the other element or intervening elements may also be present. In contrast, it will be understood that when an element is referred to as being “directly connected with” another element, there are no intervening elements present.

A singular representation may include a plural representation unless it represents a definitely different meaning from the context.

The terms such as “include” or “have” used herein are intended to indicate that features, numbers, steps, operations, elements, components, or combinations thereof used in the following description exist and it should be thus understood that the possibility of existence or addition of one or more different features, numbers, steps, operations, elements, components, or combinations thereof is not excluded.

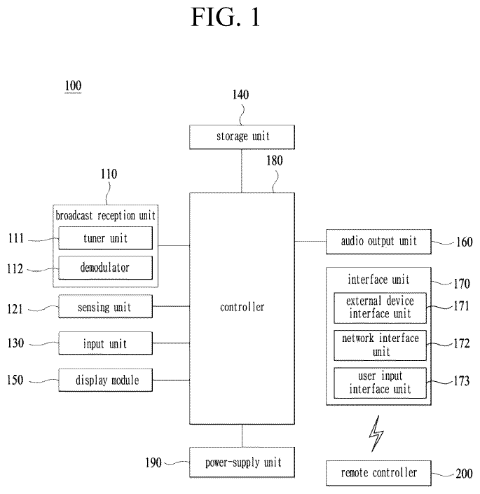

FIG. 1 is a block diagram illustrating each configuration of a display device 100 according to embodiments.

Referring to FIG. 1, a display device 100 may include a broadcast receiving unit 110, a sensing unit 120, an external device interface unit 171, a network interface unit 172, a storage unit 140, a user input interface unit 173, an input unit 130, a controller 180, a display module 150, an audio output unit 160, and/or a power supply unit 190.

The broadcast receiving unit 110 may include a tuner 111 and a demodulator 112.

Meanwhile, unlike the drawing, the display device 100 may include only the external device interface unit 171 and the network interface unit 172 among the broadcast receiving unit 110, the external device interface unit 171, and the network interface unit 172. That is, the display device 100 may not include the broadcast receiving unit 110.

The tuner unit 111 may select a broadcast signal corresponding to a channel selected by a user or all pre-stored channels from broadcast signals received through an antenna (not shown) or a cable (not shown). The tuner unit 111 may convert the selected broadcast signal into an intermediate frequency signal or a baseband video or audio signal.

For example, if the selected broadcast signal is a digital broadcast signal, the tuner unit 111 may convert the selected broadcast signal into a digital IF signal (DIF). If the selected broadcast signal is an analog broadcast signal, the tuner unit 111 may convert it into an analog baseband video or audio signal (CVBS/SIF). That is, the tuner unit 111 may process a digital broadcast signal or an analog broadcast signal. The analog baseband video or audio signal (CVBS/SIF) outputted from the tuner unit 111 may be directly inputted to the controller 180.

On the other hand, the tuner unit 111 may sequentially select broadcast signals of all stored broadcast channels through a channel memory function from the received broadcast signals and convert them into intermediate frequency signals or baseband video or audio signals.

Meanwhile, the tuner unit 111 may include a plurality of tuners to receive broadcast signals of a plurality of channels. Alternatively, a single tuner that simultaneously receives broadcast signals of a plurality of channels is also available.

The demodulator 112 may perform a demodulation operation by receiving the digital IF signal (DIF) converted by the tuner 111. The demodulator 112 may output a stream signal (TS) after performing demodulation and channel decoding. In this case, the stream signal may be a signal obtained by multiplexing a video signal, an audio signal, and/or a data signal.

The stream signal outputted from the demodulator 112 may be inputted to the controller 180. The controller 180 may output a video and an audio through the display module 150 and the audio output unit 160 after performing demultiplexing, audio/video signal processing, and the like.

The sensing unit 120 refers to a device that detects or senses a change inside or outside the display device 100. For example, it may include at least one of a proximity sensor, an illumination sensor, a touch sensor, an infrared (IR) sensor, an ultrasonic sensor, an optical sensor (e.g., a camera), a voice sensor (e.g., a microphone), a battery gauge, an environmental sensor (e.g., a humidity meter, a thermometer, etc.).

The controller 180 may check a state of the display device 100 based on the information collected by the sensing unit 120 and inform a user of it when a problem occurs or adjust it by itself to maintain a best state.

In addition, the controller 180 may provide an optimal viewing environment by controlling a content, image quality, size, etc. of a video provided to the display module 180 differently depending on a viewer, an ambient illuminance, and the like detected by the sensing unit. As smart TVs advance, the number of functions installed on display devices increases, and the sensing unit 20 is also increasing together with the functions.

The input unit 130 may be provided on one side of a body of the display device 100. For example, the input unit 130 may include a touch pad, a physical button, and the like. The input unit 130 may receive various user commands related to operations of the display device 100 and transmit control signals corresponding to the inputted commands to the controller 180.

Recently, as a bezel of the display device 100 decreases in size, many display devices 100 tend to minimize the input unit 130 in the form of physical buttons exposed to the outside. Instead, minimum physical buttons are located on a rear or side surface and a user input may be received through a touch pad, the user input interface unit 173, or a remote controller 200 to be described later.

The storage unit 140 may store a program for each signal processing and control in the controller 180, or may store a signal-processed video, audio, or data signal. For example, the storage unit 140 may store application programs designed to perform various tasks which may be processed by the controller 180, and selectively provide some of the stored application programs upon request of the controller 180.

The program and the like stored in the storage unit 140 may not be particularly limited as long as they can be executed by the controller 180. The storage unit 140 may perform a function of temporarily storing a video, audio, or data signal received from an external device through the external device interface unit 171. The storage unit 140 may store information on a prescribed broadcast channel through a channel memory function such as a channel map.

Although FIG. 1 shows an embodiment in which the storage unit 140 is provided separately from the controller 180, the scope of the present disclosure is not limited thereto, and the storage unit 140 may be included in the controller 180.

The storage unit 140 may include at least one of a volatile memory (e.g., DRAM, SRAM, SDRAM, etc.) or a nonvolatile memory (e.g., a flash memory, a Hard Disk Drive (HDD), a Solid-State Drive (SSD), etc.).

The display module 150 may generate a driving signal by converting a video signal, a data signal, an OSD signal, and a control signal processed by the controller, or a video signal, a data signal, a control signal, and the like received from the interface unit 171. The display module 150 may include a display panel including a plurality of pixels.

A plurality of the pixels included in the display panel may include RGB subpixels. Alternatively, a plurality of the pixels included in the display panel may include RGBW subpixels. The display module 150 may generate a driving signal for a plurality of the pixels by converting a video signal, a data signal, an OSD signal, a control signal, and the like processed by the controller 180.

The display module 150 may include a Plasma Display Panel (PDP), a Liquid Crystal Display (LCD), an Organic Light Emitting Diode (OLED), a flexible display (OLED), or the like, and may also include a three-dimensional (3D) display. The 3D display module 150 may be classified into a glasses-free type or a glasses type.

Meanwhile, the display module 150 may be configured as a touchscreen and used as an input device as well as an output device.

The audio output unit 160 receives an input of a signal audio-processed by the controller 180 and outputs it as an audio.

The interface unit 170 serves as a passage with various types of external devices connected to the display device 100. The interface unit 170 may include a wireless system using an antenna as well as a wired system for transmitting and receiving data through a cable.

The interface unit 170 may include at least one of a wired/wireless headset port, an external charger port, a wired/wireless data port, a memory card port, a port for connecting a device having an identification module, an audio Input/Output (I/O) port, a video Input/Output (I/O) port, an earphone port, etc.

As an example of the wireless system, the above-described broadcast receiving unit 110 may be included, and not only a broadcast signal but also a mobile communication signal, a short-range communication signal, a wireless Internet signal, and the like may be included.

The external device interface unit 171 may transmit or receive data to or from a connected external device. To this end, the external device interface unit 171 may include an A/V input/output unit (not shown).

The external device interface unit 171 may be connected to an external device such as a Digital Versatile Disk (DVD), a Blu-ray, a game device, a camera, a camcorder, a computer (a notebook), a set-top box, and the like by wire or wirelessly, and may perform input/output operations with the external device.

In addition, the external device interface unit 171 may establish a communication network with various remote controllers 200 to receive control signals related to the operation of the display device 100 from the remote controller 200 or transmit data related to the operation of the display device 100 to the remote controller 200.

The external device interface unit 171 may include a wireless communication unit (not shown) for short-range wireless communication with another electronic device. Through the wireless communication unit (not shown), the external device interface unit 171 may exchange data with an adjacent mobile terminal. Particularly, in a mirroring mode, the external device interface unit 171 may receive device information, executed application information, application image, and the like from the mobile terminal.

The network interface unit 172 may provide an interface for connecting the display device 100 to a wired/wireless network including an Internet network. For example, the network interface unit 172 may receive content or data provided by Internet, a content provider, or a network operator over a network. Meanwhile, the network interface unit 172 may include a communication module (not shown) for connection with a wired/wireless network.

The external device interface unit 171 and/or the network interface unit 172 may include a communication module for short-range communication such as Wireless-Fidelity (Wi-Fi), Bluetooth, Bluetooth Low Energy (BLE), Zigbee, and Near Field Communication (NFC), a communication module for cellular communication such as Long-Term Evolution (LTE), LTE-Advance (LTE-A), Code Division Multiple Access (CDMA), Wideband CDMA (WCDMA), Universal Mobile Telecommunications System (UMTS), Wireless Broadband (WiBro), and the like.

The user input interface unit 173 may transmit a signal inputted by a user to the controller 180, or transmit a signal from the controller 180 to the user. For example, it may transmit/receive a user input signal such as power on/off, channel selection, screen setting, and the like to/from the remote controller 200, forward a user input signal inputted from a local key (not shown) such as a power key, a channel key, a volume key, a setting value, and the like to the controller 180, forward a user input signal inputted from a sensor unit (not shown) that senses a user's gesture to the controller 180, or transmit a signal from the controller 180 to the sensor unit.

The controller 180 may include at least one processor, and may control the overall operation of the display device 100 by using a processor included therein. Here, the processor may include a general processor such as a Central Processing Unit (CPU). Of course, the processor may include a dedicated device such as an ASIC or another hardware-based processor.

The controller 180 may generate and output a signal for a video or audio output by demultiplex a stream inputted through the tuner 111, the demodulator 112, the external device interface unit 171, or the network interface unit 172 or processing the demultiplexed signals.

The video signal video-processed by the controller 180 may be inputted to the display module 150 and displayed as a video corresponding to the video signal. In addition, the video signal video-processed by the controller 180 may be inputted to an external output device through the external device interface unit 171.

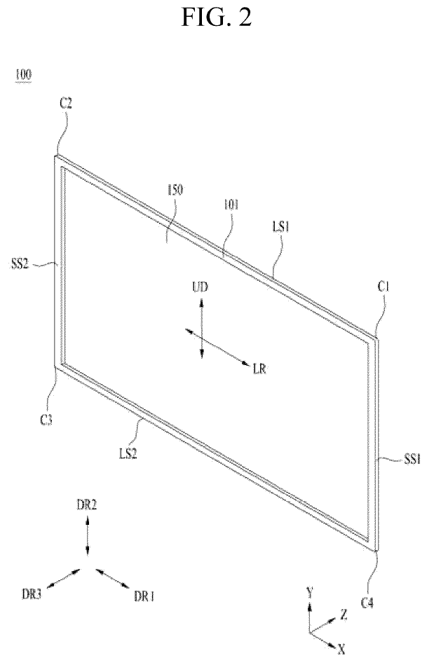

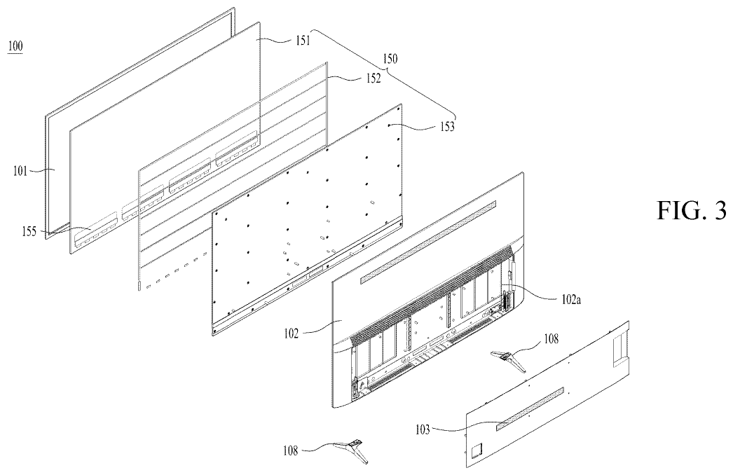

The audio signal processed by the controller 180 may be outputted to the audio output unit 160. Also, the audio signal processed by the controller 180 may be inputted to an external output device through the external device interface unit 171. Although not shown in FIG. 2, the controller 180 may include a demultiplexing unit, a video processing unit, and the like. This will be described later with reference to FIG. 3.

Besides, the controller 180 may control the overall operation of the display device 100. For example, the controller 180 may control the tuner 111 to select (e.g., tune) a broadcast corresponding to a channel selected by a user or a pre-stored channel.

In addition, the controller 180 may control the display device 100 by a user command inputted through the user input interface unit 173 or an internal program. Meanwhile, the controller 180 may control the display module 150 to display an image. In this case, the image displayed on the display module 150 may be a still image or a moving image, and may be a 2D image or a 3D image.

Meanwhile, the controller 180 may display a predetermined 2D object in the image displayed on the display module 150. For example, the object may include at least one of a connected web screen (e.g., newspaper, magazine, etc.), an Electronic Program Guide (EPG), one of various menus, a widget, an icon, a still image, a moving image, and texts.

Meanwhile, the controller 180 may modulate and/or demodulate a signal using an Amplitude Shift Keying (ASK). Here, the amplitude shift modulation (ASK) may mean a method of modulating a signal by varying the amplitude of a carrier wave according to a data value or restoring an analog signal to a digital data value according to the amplitude of the carrier wave.

For example, the controller 180 may modulate a video signal using Amplitude Shift Keying (ASK) and transmit it through a wireless communication module.

For example, the controller 180 may demodulate and process a video signal received through a wireless communication module using Amplitude Shift Keying (ASK).

Through this, the display device 100 may easily transmit and receive signals to and from other adjacent image display devices without using a unique identifier such as a Media Access Control (MAC) address or a complex communication protocol such as TCP/IP.

Meanwhile, the display device 100 may further include a photographing unit (not shown). The photographing unit may photograph a user. The photographing unit may be implemented with a single camera, but is not limited thereto, and may also be implemented with a plurality of cameras. Meanwhile, the photographing unit may be embedded in an upper portion of the display module 150 of the display device 100 or separately disposed. Image information photographed by the photographing unit may be inputted to the controller 180.

The controller 180 may recognize a user's location based on an image photographed by the photographing unit. For example, the controller 180 may recognize a distance (e.g., a z-axis coordinate) between the user and the display device 100. In addition, the controller 180 may recognize an x-axis coordinate and a y-axis coordinate in the display module 150 corresponding to the user's location.

The controller 180 may detect a user's gesture based on an image photographed by the photographing unit, each signal sensed from the sensor unit, or a combination thereof.

The power supply unit 190 may supply corresponding power to the display device 100 overall. In particular, power may be supplied to the controller 180, which may be implemented in the form of a System-On-Chip (SOC), the display module 150 for displaying an image, the audio output unit 160 for audio output, etc.

Specifically, the power supply unit 190 may include a converter (not shown) that converts AC power into DC power, and a Dc/Dc converter (not shown) that converts a level of the DC power.

Meanwhile, the power supply unit 190 serves to receive power from the outside and distribute the power to each component. The power supply unit 190 may use a method of supplying AC power by directly connecting with external power, and a power supply unit 190 usable in a manner of charging a battery included therein may be included.

In the former case, a wired cable is connected and used, and movement is difficult or a range of movement is limited. In the latter case, although it is free to move, the weight and volume increase as much as the battery, and for charging, it should be connected to a power cable directly for a predetermined time or combined with a charging holder (not shown) that supplies power.

The charging holder may be connected to the display device through a terminal exposed to the outside, or a built-in battery may be charged when the charging holder is approached using a wireless method.

The remote controller 200 may transmit a user input to the user input interface 173. To this end, the remote controller 200 may use Bluetooth, Radio Frequency (RF) communication, Infrared Radiation (IR) communication, Ultra-WideBand (UWB), ZigBee, etc. In addition, the remote controller 200 may receive a video, an audio, a data signal, or the like outputted from the user input interface unit 173 and the received image, audio, data signal or the like may be displayed or outputted by the remote controller 200.

Meanwhile, the above-described display device 100 may include a stationary or mobile digital broadcast receiver capable of receiving digital broadcasting.

Meanwhile, the block diagram of the display device 100 shown in FIG. 1 is only a block diagram for an embodiment of the present disclosure, and each component of the block diagram may be integrated, added, or omitted depending on the specifications of the display device 100 that is actually implemented.

That is, two or more components may be combined or integrated into one component, or one component may be subdivided into two or more components as necessary. In addition, a function performed in each block is for describing an embodiment of the present disclosure, and a specific operation or device does not limit the scope of rights of the present disclosure.

FIG. 2 is a perspective diagram illustrating an example of a display device according to embodiments.

A display device 100 illustrated in FIG. 2 corresponds to the display device 100 illustrated in FIG. 1.

Referring to FIG. 2 together with FIG. 1, the display device 100 may have a rectangular shape including a first long side LS1, a second long side LS2 facing the first long side LS1, a first short side SS1 adjacent to the first long side LS1, and a second short side SS2 facing the first short side SS1.

Here, a first short side area SS1 is referred to as a first side area, a second short side area SS2 is referred to as a second side area facing the first side area, a first long side area LS1 is referred to as a third side area adjacent to the first side area and the second side area and located between the first side area and the second side area, and a second long side area LS2 is referred to as a fourth side area adjacent to the first side area and the second side area, located between the first side area and the second side area, and facing the third side area.

In addition, depending on the convenience of explanation, the length of the first/second long side LS1/LS2 is shown and described to be longer than that of the first/second short side SS1/SS2, but it may also be possible when the length of the first/second long side LS1/LS2 is approximately the same as that of the first/second short side SS1/SS2.

Furthermore, hereinafter, a first direction DR1 may be a direction parallel to the long sides LS1 and LS2 of the display device 100, and a second direction DR2 may be a direction parallel to the short sides SS1 and SS2 of the display device 100. A third direction DR3 may be a direction vertical to the first direction DR1 and/or the second direction DR2.

From another point of view, a side on which the display device 100 displays an image may be referred to as a front or a front surface. When the display device 100 displays an image, a side on which the image cannot be observed may be referred to as a rear or rear surface. When the display device 100 is viewed from the front or the front surface, a side toward the first long side LS1 may be referred to as an upper side or an upper surface. Similarly, a side toward the second long side LS2 side may be referred to as a lower side or a lower surface. Similarly, a side toward the first short side SS1 may be referred to as a right side or a right surface, and a side toward the second short side SS2 may be referred to as a left side or a left surface.

In addition, the first long side LS1, the second long side LS2, the first short side SS1, and the second short side SS2 may be referred to as edges of the display device 100. In addition, points at which the first long side LS1, the second long side LS2, the first short side SS1, and the second short side SS2 meet each other may be referred to as corners. For example, a point at which the first long side LS1 meets the first short side SS1 may be a first corner C1, a point at which the first long side LS1 meets the second short side SS2 may be a second corner C2, a point at which the second short side SS2 meets the second long side LS2 may be a third corner C3, and a point at which the second long side LS2 meets the first short side SS1 may be a fourth corner C4.

Here, a direction from the first short side SS1 to the second short side SS2 or a direction from the second short side SS2 to the first short side SS1 may be referred to as a left-right direction LR. A direction from the first long side LS1 to the second long side LS2 or a direction from the second long side LS2 to the first long side LS1 may be referred to as an upward-downward direction UD.

A display device includes a display module that occupies most of the area of a front surface and a case covering a rear surface, a side surface and the like of the display module and packaging the display module.

Recently, the display device 100 may use the display module 150 that may be bent, such as Light Emitting Diodes (LEDs) or Organic Light Emitting Diodes (OLEDs), to implement a curved screen further from a plane.

The LCD, which has been mainly used in the related art, is supplied with light through a backlight unit because it is difficult to emit light by itself. The backlight unit is a device that uniformly supplies a light supplied from a light source to liquid crystals located in front. As the backlight unit becomes thinner and thinner, a thin LCD could be implemented, but it is difficult to implement the backlight unit with a bent material, and when the backlight unit is bent, it is difficult to uniformly supply light to the liquid crystals, and thus there is a problem that brightness of a screen changes.

On the other hand, in the case of LED and OLED, since a device constituting a pixel emits light by itself, the LED or OLED may be implemented to be bent without using a backlight unit. In addition, since each device emits light by itself, even if the positional relationship with a neighboring device is changed, it does not affect its brightness, so the display module 150 that is bendable may be implemented using LED or OLED.

Organic Light Emitting Diodes (OLED) panels appeared in earnest in mid-2010 and are rapidly replacing LCDs in the small and medium-sized display market. An OLED is a display made using a self-luminous effect that emits light when current flows through a fluorescent organic compound, and an image quality reaction speed is faster than that of LCD, so afterimage hardly appears when implementing a moving image.

OLED uses three types of phosphor organic compounds, Red, Green, and Blue, which have their own light-emitting functions. Since it is a light-emitting display product that uses an effect in which electrons and positively charged particles injected from the cathode and the anode combine in an organic material to emit light on their own, there is no need for a backlight (backlight device) to reduce color sense.

A Light Emitting Diode (LED) panel uses a single LED device as a single pixel, and may implement a flexible display module 150 by reducing a size of a LED device compared to the related art. Conventionally, a device called an LED TV uses LED as a light source for a backlight unit that supplies light to LCD, but the LED itself fails to constitute a screen.

A display module includes a display panel, a coupling magnet positioned on a rear surface of the display panel, a first power supply unit, and a first signal module. The display panel may include a plurality of pixels R, G, and B. A plurality of the pixels R, G, and B may be formed in each region where a multitude of data lines and a multitude of gate lines cross each other. A plurality of the pixels R, G, and B may be disposed or arranged in a matrix form.

For example, a plurality of the pixels R, G, and B may include a Red (R) subpixel, a Green (G) subpixel, and a Blue (B) subpixel. A plurality of the pixels R, G, and B may further include a White (W) subpixel.

A side of the display module 150, on which an image is displayed, may be referred to as a front or a front surface. When displaying an image, a side of the display module 150, on which the image cannot be observed, may be referred to as a rear or a rear surface.

FIG. 3 is an exploded perspective diagram illustrating an example of a display device according to embodiments.

A display device 100 illustrated in FIG. 3 corresponds to the display device 100 illustrated in FIG. 1 and FIG. 2.

The display device 100 may include a display module 150, a case top 101 covering a front circumference of the display module 150 as well as a side circumference, a bottom cover 102 covering a rear surface of the display module 150, and a back cover 103 covering components mounted on a rear surface 102a of the bottom cover 102 and coupled to the rear surface of the bottom cover 102.

As the display module 150 has recently become thinner, a housing 101 and 102 is also becoming thinner, and the thickness of the case top 101 constituting a bezel located on a front circumference of the display module 150 may be reduced or omitted. For example, in the case of an OLED panel, a backlight unit is omitted and a layered structure exposed in a lateral direction is simpler than that of a liquid crystal display panel, so the case top 101 may be omitted.

The display module 150 includes a display panel 151 through which an image is outputted and a support panel 153 for supporting a rear surface of the display panel 151, and the two members may be coupled using an adhesive member 152 such as OCA.

A flexible board 155 extending from an end portion of the display panel 151 may be bent in a rear direction to be connected to a control board e mounted on the bottom cover 102. When a liquid crystal panel is used, the display panel 151 may be configured by seating a light source board, an optical sheet, and a liquid crystal panel in order using a panel guide.

In a mounting form of hanging on a wall, a structure (not shown) fastened to the wall is included in a rear surface of the display device 100. And, the display device 100 standing to be mounted on the floor may include a stand 108 extending from a lower portion of the display module 150.

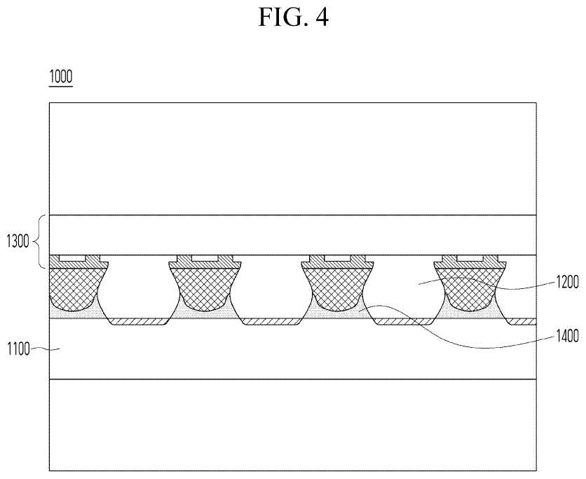

FIG. 4 is a diagram illustrating a circuit device according to embodiments.

A circuit device 1000 illustrated in FIG. 4 may correspond to a circuit device provided inside the display device 100 illustrated in FIGS. 1 to 3.

Referring to FIG. 4, a circuit device 1000 according to embodiments may include a board 1100, an electronic component 1200, an Integrated Circuit (IC) chip 1300, and a coating layer 1400.

The board 1100 may correspond to a member connected to a power source provided with a wiring for supplying a signal or current required for driving, and may include, for example, a Printed Circuit Board (PCB). The board 1100 may provide a driving signal to the display module 150 or the display panel shown in FIG. 1 and FIG. 2.

The IC chip 1300 may vary according to a type of electronic device such as a semiconductor chip package, a light emitting diode chip package, and the like, and is a member capable of performing electrical signal processing.

The electronic component 1200 is a component mounted on the board 1100 and may include an electrode or the like. More specifically, a lower surface of the electronic component 1200 may meet the board 1100 and an upper surface thereof may meet the IC chip 1300. That is, the electronic component 1200 may correspond to a conductive member for transmitting an electrical signal or current to the IC chip 1300 located on an upper portion of the board 1100.

Accordingly, the electronic component 1200 may correspond to any conductive member, and may preferably correspond to an electrode. In this case, the electronic component 1200 may be formed by soldering. A plurality of the electronic components 1200 may be included.

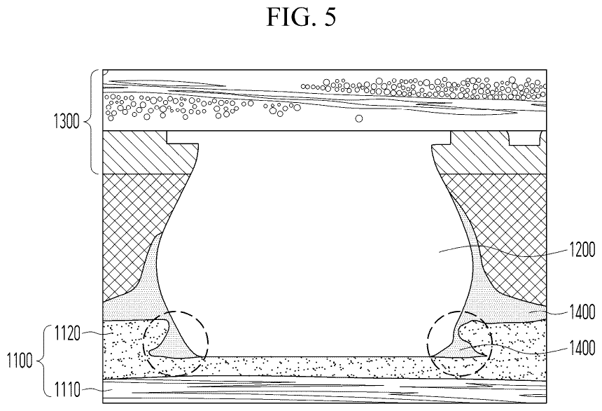

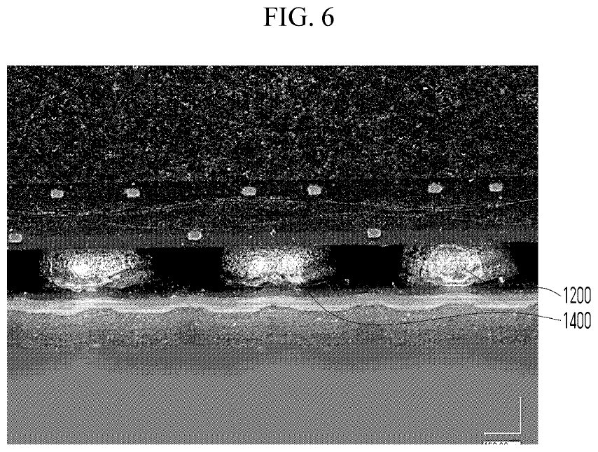

The coating layer 1400 may surround a portion of a side surface of the electronic component 1200, and an upper surface thereof may be formed to be spaced apart from the IC chip 1300. That is, the coating layer 1400 may surround an exposed side circumference of the electronic component 1200 connecting the board 1100 and the IC chip 1300. In this case, the coating layer 1400 may be formed not to entirely surround a side circumference of the electronic component 1200, and not to partially surround the side circumference of the electronic component 1200. The coating layer 1400 will be described in more detail with reference to FIG. 5 and FIG. 6.

FIG. 5 is an enlarged diagram illustrating an electronic component of a circuit device according to embodiments.

FIG. 5 is an enlarged view of the electronic component 1200 of the circuit device 1000 shown in FIG. 4.

Referring to FIG. 4 together, the coating layer 1400 may surround a portion of a side surface of the electronic component 1200 and an upper portion of the board 1100. That is, the coating layer 1400 may surround a lower end portion of the side surface of the electronic component 1200 and the upper portion of the board 1100, and the electronic component 1200 and the board 1100 may be protected from moisture by the coating layer 1400.

Referring to FIG. 5, the board 1100 may include a support layer 1110 and a protective layer 1120. The protective layer 1120 may be formed on an upper portion of the support layer 1110, and may protect the support layer 1110. For example, the protective layer 1120 may correspond to a layer formed by a Photo Solder Resist (PSR) process of coating an immutable ink on an upper surface of the support layer 1110.

The protective layer 1120 may protect the support layer 1110 from moisture while being formed on an upper portion of the support layer 1110. However, there is a problem that a gap may be formed between the protective layer 1120 and the support layer 1110 due to the electronic component 1200 formed on the support layer 1110, and thus moisture may permeate through the gap.

Accordingly, the coating layer 1400 of the circuit device 1000 according to embodiments may be formed by partially overlapping the protective layer 1120. That is, the coating layer 1400 may be formed by overlapping a space where the electronic component 1200 and the protective layer 1120 meet (denoted by a circle). Since the coating layer 1400 is formed by partially overlapping the protective layer 1120, the circuit device 1000 according to embodiments may block the electronic component 1200 from moisture, etc.

The coating layer 1400 may be formed of a mixture including an epoxy component. The mixture may correspond to a solder paste. More specifically, the electronic component 1200 may be adhered onto the board 1100 by using the solder paste. In this case, the solder paste may be separated into the coating layer 1400 and the solder surrounding the electronic component 1200 or forming the electronic component 1200 by a reflow process.

The solder paste is a mixture of an epoxy binder composed of an epoxy component and a solder powder, and the solder powder may be changed into solder through a reflow process, and the epoxy binder may change into the coating layer 1400. That is, unlike a solder paste generally composed of a flux and solder particles, the solder paste used in the circuit device 1000 according to the embodiments, i.e., the mixture is characterized in not using a flux.

In this case, a content of the epoxy binder included in the solder paste may correspond to 8 to 12 wt %. In other words, the content of the epoxy component included in the mixture may correspond to 8 to 12 wt %. More specifically, the content of the epoxy component included in the mixture preferably corresponds to 9 to 11 wt %.

The coating layer 1400 may surround the circumference of the side surface of the electronic component 1200 by surface tension. And, a height of the coating layer 1400 may be lowered as a distance from the electronic component 1200 increases due to surface tension. For example, when two electronic components 1200 are formed, the height of the coating layer 1400 decreases as the distance from the first electronic component 1200 decreases. And, the height of the coating layer 1400 may increase as the second electronic component 1200 approaches again.

Accordingly, the height of the coating layer 1400 formed close to the electronic component 1200 may be formed higher than that of the coating layer 1400 formed far from the electronic component 1200. In other words, a highest uppermost portion of the coating layer 1400 may be formed on the side surface of the electronic component 1200.

Furthermore, as described in FIG. 3 and FIG. 4, the coating layer 1400 may not completely surround the circumference of the side surface of the electronic component 1200 and may not surround the coating layer 1400 in part. That is, the highest uppermost portion of the coating layer 1400 may be positioned to be spaced apart from a lower end of the IC chip 1300. In this case, a distance from the highest uppermost portion of the coating layer 1400 to the lower end of the IC chip 1300 may be less than half of the height of the electronic component 1200.

In this case, the content of the epoxy binder included in the solder paste may correspond to 8 to 12 wt %. In other words, the content of the epoxy component included in the mixture may correspond to 8 to 12 wt %. More specifically, it may be preferable that the content of the epoxy component included in the mixture corresponds to 9 to 11 wt %.

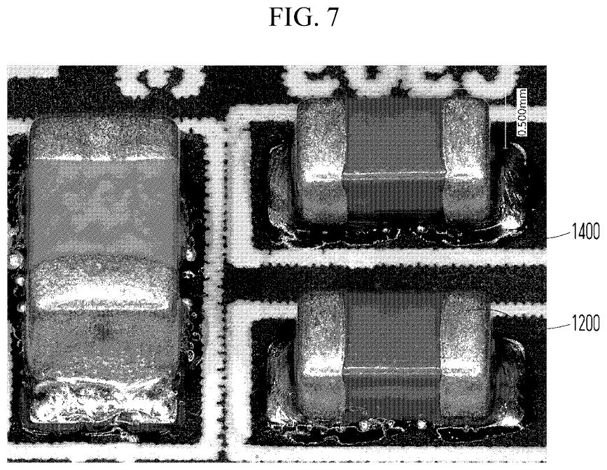

FIG. 6 and FIG. 7 are diagrams illustrating examples of circuit devices according to embodiments.

More specifically, FIG. 6 is a diagram illustrating an example of a circuit device in which an electrode is formed, and FIG. 7 is a diagram illustrating an example of a circuit device in which an electronic component is formed.

Referring to FIG. 6 and FIG. 7, the coating layer 1400 may surround a side circumference of the electrode or the electronic component 1200. More specifically, the coating layer 1400 may surround a portion, not all, of the side circumference of the electrode or the electronic component 1200.

Accordingly, the circuit device 1000 according to the embodiments may prevent moisture from permeating into the electrode or electronic component 1200 even in areas where the temperature is high and humid, such as Southeast Asia, thereby preventing short circuit.

The detailed description of the preferred embodiments of the present disclosure disclosed as described above has been provided to allow those skilled in the art to embody and implement the present disclosure. Although the above has been described with reference to the preferred embodiments of the present disclosure, those skilled in the art will understand that the present disclosure may be variously modified and changed without departing from the scope of the present disclosure. For example, those skilled in the art may use each of the components described in the above-described embodiments in a manner of combining them with each other.

Therefore, the present disclosure is not intended to be limited to the embodiments shown here, but to give a broadest scope consistent with the principles and new features disclosed herein.

What is claimed is:

1. A circuit device, comprising:
a board;
an electronic component mounted on the board;
an IC chip meeting an upper surface of the electronic component; and
a coating layer partially surrounding a side surface of the electronic component and having an upper surface spaced apart from the IC chip.

2. The circuit device of claim 1, wherein the coating layer surrounds an upper surface of the substrate.

3. The circuit device of claim 1, the board comprising:
a support layer; and
a protective layer located on the support layer,
wherein a portion of the coating layer surrounds the side surface of the electronic component while overlapping the protective layer.

4. The circuit device of claim 1, wherein a height of the coating layer decreases in proportion to a distance from the electronic component.

5. The circuit device of claim 1, wherein a distance from the upper surface of the coating layer to the IC chip is formed smaller than a half of a height of the electronic component.

6. The circuit device of claim 1, wherein the coating layer is formed by a mixture containing an epoxy component.

7. The circuit device of claim 6, wherein a content of the epoxy component contained in the mixture amounts to 8 to 12 wt %.

8. A display device, comprising:
a display panel;
a board providing a driving signal to the display panel;
an electronic component mounted on the board;
an IC chip meeting an upper surface of the electronic component; and
a coating layer partially surrounding a side surface of the electronic component and having an upper surface spaced apart from the IC chip.

9. The display device of claim 8, wherein the coating layer surrounds an upper surface of the substrate.

10. The display device of claim 8, the board comprising:
a support layer; and
a protective layer located on the support layer,
wherein a portion of the coating layer surrounds the side surface of the electronic component while overlapping the protective layer.

11. The display device of claim 8, wherein a height of the coating layer decreases in proportion to a distance from the electronic component.

12. The display device of claim 8, wherein a distance from the upper surface of the coating layer to the IC chip is formed smaller than a half of a height of the electronic component.

13. The display device of claim 8, wherein the coating layer is formed by a mixture containing an epoxy component.

14. The display device of claim 13, wherein a content of the epoxy component contained in the mixture amounts to 8 to 12 wt %.
